(19) United States
(12) Patent Application Publication
(10) Pub. No.: US 2008/0309333 A1
(43) Pub. Date: Dec. 18, 2008

(54) Motion-Dependent Data Acquisition in Magnetic Resonance Imaging and Spectroscopy

(75) Inventors: Christian Stehning, Hamburg (DE); Peter Boernert, Hamburg (DE)

Correspondence Address: PHILIPS INTELLECTUAL PROPERTY & STANDARDS, 595 MINER ROAD, CLEVELAND, OH, 44143, US

(73) Assignee: KONINKLIJKE PHILIPS ELECTRONICS N. V., Eindhoven (NL)

(21) Appl. No.: 12/097,550

(22) PCT Filed: Dec. 19, 2006
(86) PCT No.: PCT/IB06/54946

§ 371 Date: Jun. 16, 2008

(30) Foreign Application Priority Data
Dec. 21, 2005 (EP) 05112542.5

(51) Int. Cl. G01R 33/54

(52) U.S. Cl. 324/307

(57) ABSTRACT

The invention relates to a magnetic resonance (MR) system for acquiring MR data from a subject (105), the MR system comprising a monitoring module (117) for monitoring a characteristic of a motion of the subject, the characteristic of the motion having a pre-determined or dynamically adjusted limit (119), and a pulse sequencer (108) for applying a pulse sequence to acquire data from the subject (105) when the characteristic of the motion is within the limit (119), the pulse sequence comprising at least one pulse waveform, wherein the pulse sequencer (108) is further arranged to regulate a characteristic of the at least one pulse waveform when the characteristic of the motion surpasses the limit (119).

The invention relates to a magnetic resonance (MR) system for acquiring MR data from a subject, the MR system comprising a monitoring module for monitoring a characteristic of a motion of the subject, the characteristic of the motion having a limit, and a pulse sequencer for applying a pulse sequence to acquire data from the subject, the pulse sequence comprising at least one pulse waveform.

The invention further relates to a method of acquiring MR data from a subject, the method comprising the steps of monitoring a characteristic of a motion of the subject, the characteristic of the motion having a limit, and applying a pulse sequence to acquire data from the subject, the pulse sequence comprising at least one pulse waveform.

The invention further relates to a computer program for such a magnetic resonance system, the computer program further comprising instructions for monitoring a characteristic of a motion of a subject, the characteristic of the motion having a limit, and for applying a pulse sequence to acquire data from the subject, the pulse sequence comprising at least one pulse waveform, when the program is run on a computer.

An implementation of such a method is described in U.S. Pat. No. 6,144,874A, wherein MR data required to reconstruct an image are divided into central k-space views and peripheral k-space views. MR navigator signals are acquired during a scan to indicate patient respiration and a first gating signal is produced when respiration is within a narrow acquisition window and a second gating signal is produced when respiration is within a wider acquisition window. Central views are acquired in k-space, when the first gating signal is produced and peripheral k-space views are acquired when the second gating signal is produced. If the respiration signal is outside the specified acquisition windows, no gating signal is indicated, and acquired image data are discarded. The system then loops back to acquire another navigation signal and the steps are repeated to determine if image data can be acquired. When all the k-space views have been acquired, the image is reconstructed.

A problem with the prior art is that the multiple loops required both to determine if image data can be acquired, as well as to acquire all the k-space views that are required to reconstruct an image, could lead to increased RF deposition, which could compromise patient comfort and safety.

It is thus an object of the invention to provide an MR system that, when in operation, provides increased comfort and safety of a subject being examined.

This object is achieved by an MR system according to the opening paragraph, wherein the pulse sequencer is further arranged to regulate a characteristic of the at least one pulse waveform when the characteristic of the motion surpasses the limit. The at least one pulse waveform comprises an RF pulse or a combination of RF and gradient pulses. The monitoring module monitors the characteristic of the motion of the subject. If the characteristic of the motion exceeds the limit, the pulse sequencer regulates at least one component of the pulse waveform, for example the RF pulse or the gradient pulse, by temporarily increasing or decreasing at least one characteristic of the component, for example the pulse duration, the pulse power, the number of pulses, etc.

By reducing the number, the power or the duration of RF pulses, the specific absorption rate (SAR) in the subject is reduced, thus leading to increased safety. Lower SAR values also result in reduced localized heating in the subject, resulting in increased subject comfort. Alternatively, the reduced average SAR deposition obtained with the invention can be used to allow for optimized MR pulse sequences, without exceeding SAR limits. If the power, the duration or the number of gradient pulses is reduced, the subject's comfort is enhanced, as fewer gradients result in less noise, and in reduced peripheral nerve stimulation. Fewer gradient pulses also enhance patient safety, since gradient pulses can set up eddy currents in metallic objects adjacent to or inside the subject's body, causing localized heating, possibly leading to burn injuries. Alternatively, it is also possible to increase the power, duration or number of applied RF or gradient pulses, depending on the characteristic of the monitored motion. For example, the pulse power of preparatory RF pulses could be increased to quickly attain steady state before the start of data acquisition. As another example, the pulse power level of an RF pulse could be increased while its duration is reduced such that the required flip angle is obtained using a shorter duration RF pulse.

This and other aspects of the invention will be elaborated further on the basis of the following embodiments, which are defined in the dependent claims.

In an embodiment of the MR system according to the invention, the at least one pulse waveform comprises a radio frequency (RF) pulse. When the characteristic of the motion, for example its displacement, velocity, acceleration, etc., crosses the limit, a characteristic of the pulse waveform, for example the power level of the RF pulse or its duration or the number of pulses, is regulated. A combination of the above pulse waveform characteristics may also be regulated.

In a further embodiment of the MR system according to the invention, the at least one pulse waveform comprises a combination of RF and gradient pulses. When the characteristic of the motion, for example its displacement, velocity, acceleration, etc., goes beyond the limit, a characteristic of the gradient pulse, for example, its power level, its duration, or the number of pulses, is regulated.

In a further embodiment of the MR system according to the invention, the characteristic of the at least one pulse waveform, for example the pulse amplitude or the pulse width, is adjusted to a minimum value, preferably zero. It is recognized in the prior art that subject motion causes artifacts in MR images. Often data, acquired when the subject motion is deemed excessive, is not considered during reconstruction of the image. Such missing data, for example a few lines of k-space, are re-acquired when the subject motion is within acceptable limits. However, as the pulse sequence is applied regardless of whether the acquired data are used in reconstruction or not, the subject is unnecessarily exposed to unproductive RF or gradient pulses, i.e., RF or gradient pulses which do not contribute to the final image. In the current embodiment, when the characteristic of the motion being monitored goes beyond a limit, a characteristic of the at least one pulse waveform, for example the pulse amplitude or the pulse duration or the number of pulses, is reduced. By reducing, or even stopping the application of unproductive RF and gradient pulses, the comfort and safety of the subject is improved. Alternatively, the reduced average SAR deposition obtained with the invention can be used to allow for optimized MR pulse sequences, without exceeding SAR limits.

It is a further object of the invention to provide a method of acquiring MR data from a subject, wherein the method provides increased comfort and safety of the subject being examined.

This object is achieved by a method according to the opening paragraphs, wherein a characteristic of the at least one pulse waveform is regulated when the characteristic of the motion surpasses the limit. For example, a characteristic of a motion of a subject, for example the rate of change of position of a portion of the subject is monitored, the rate of change of position having a limit. When the rate of change of position is within the limit, an RF pulse of a particular power and duration is applied. When the rate of change of position exceeds the limit, the pulse duration is reduced while the pulse power is increased appropriately such that the flip angle of the RF pulse is maintained. Thus, based on the monitored characteristic, a shorter- or a longer-duration RF pulse is applied, without compromising the effectiveness of the pulse. The SAR deposition is limited on average, which allows for optimized MR pulse sequences for increased image quality without exceeding SAR limits. As another example, the displacement of a portion of the subject is monitored, the displacement having a pre-determined maximum limit. If the displacement of the portion of the subject exceeds the pre-determined maximum limit, the at least one pulse waveform is regulated, for example by temporarily minimizing at least one of the components of the pulse waveform, for example an RF pulse or a gradient pulse. This reduces unnecessary exposure of the subject to RF and gradient pulses, thus providing improved safety and comfort.

It is a further object of the invention to provide a computer program to be loaded by a computer arrangement, the computer program comprising instructions for acquiring MR data from an MR system that, when in operation, provides increased comfort and safety of a subject being examined. It is also a further object of the invention to provide a computer program product comprising the above computer program.

This object is achieved by a computer program according to the opening paragraphs, wherein the computer program further comprises instructions for regulating a characteristic of the at least one pulse waveform when the characteristic of the motion surpasses the limit. For example, if the characteristic of the motion exceeds the limit, the computer program instructs the pulse sequencer to regulate the at least one pulse waveform, for example by temporarily minimizing an RF pulse or a gradient pulse or both. This reduces unnecessary exposure of the subject to RF and gradient pulses, thus providing improved safety and comfort. The computer program product comprises the computer program residing on a computer readable medium, for example a CD-ROM or a DVD. Alternatively, the computer program product could be a downloadable program that is downloaded, or otherwise transferred to the computer, for example via the Internet.

These and other aspects of the invention will be described in detail hereinafter, by way of example, on the basis of the following embodiments, with reference to the accompanying drawings wherein,

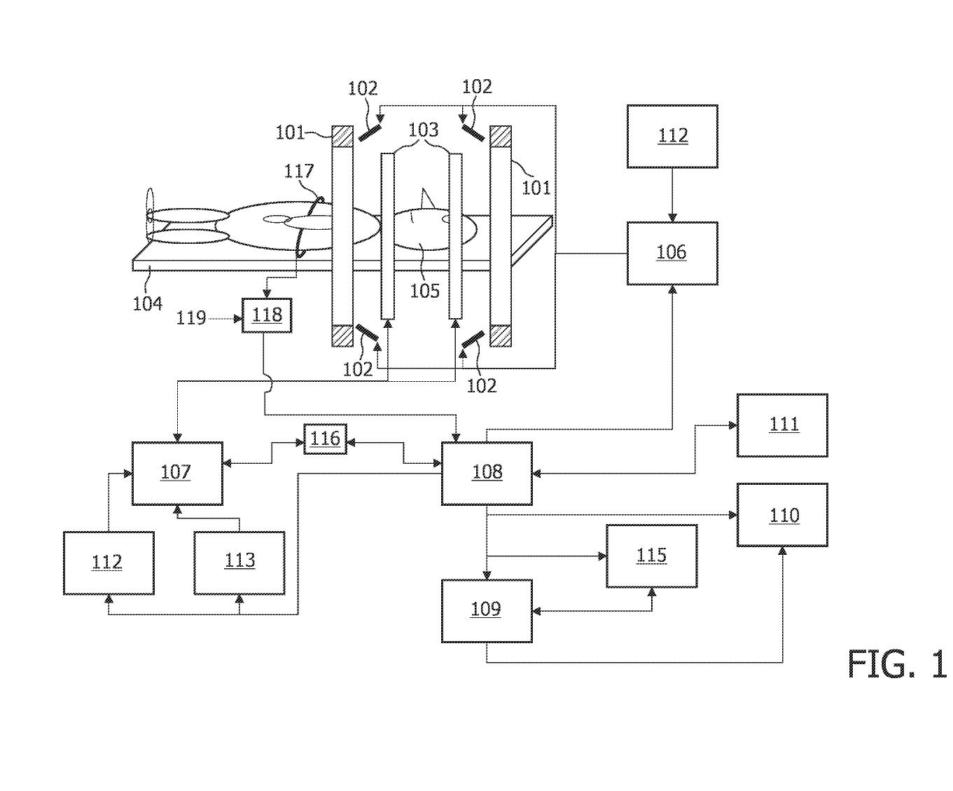

FIG. 1 schematically shows an MR system according to the invention, wherein the MR system, when in operation, provides increased comfort and safety of a subject being examined,

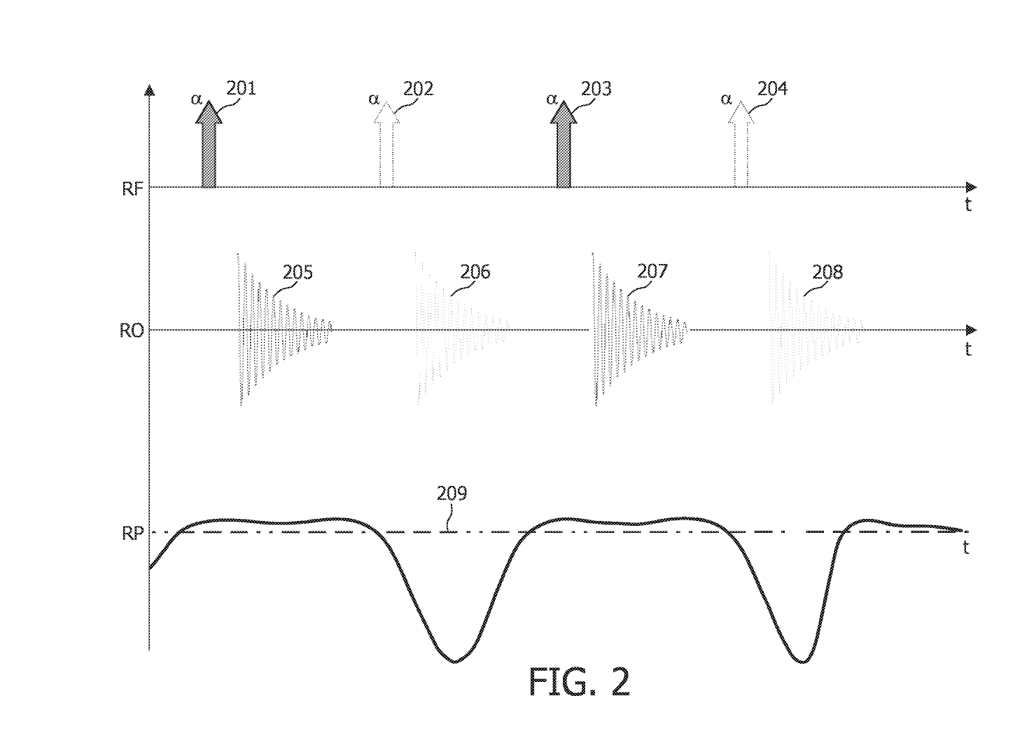

FIG. 2 diagrammatically shows a “one-pulse” MR spectroscopy sequence, wherein the RF pulse has been regulated,

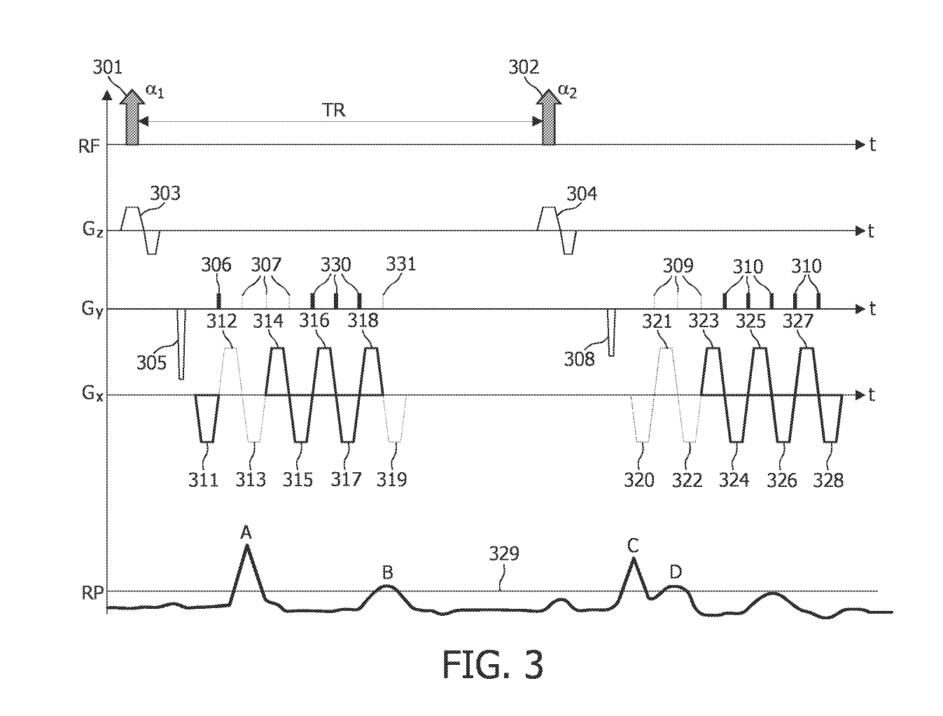

FIG. 3 diagrammatically shows an echo planar imaging (EPI) pulse waveform, wherein gradient pulses along the phase encode and the readout axes have been regulated,

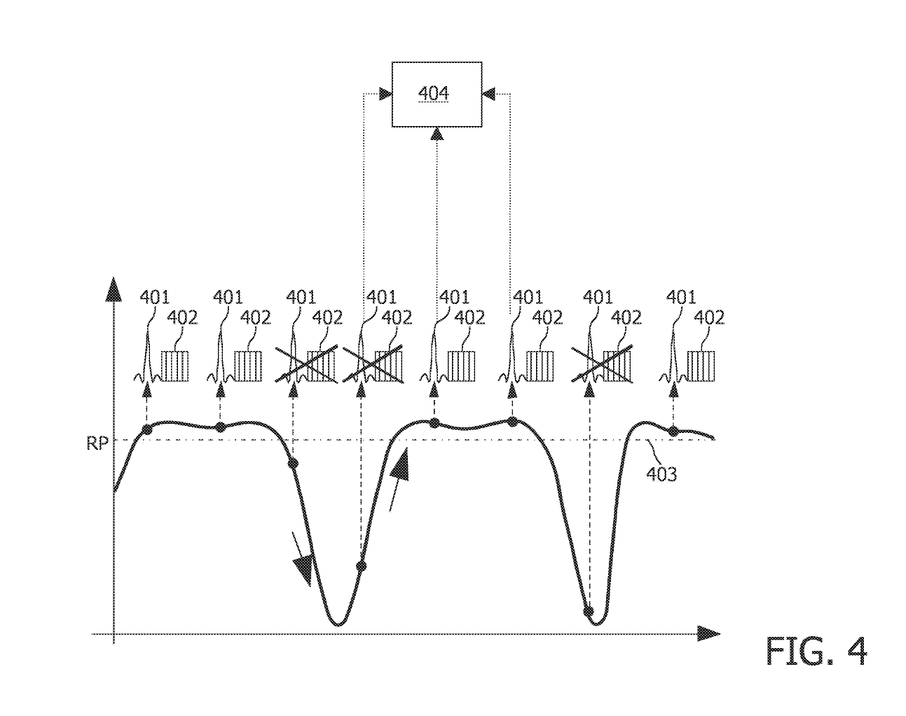

FIG. 4 diagrammatically shows an illustrative pulse waveform, wherein an RF pulse and/or a gradient pulse, is minimized, or even stopped completely, when the characteristic of a monitored motion exceeds a limit,

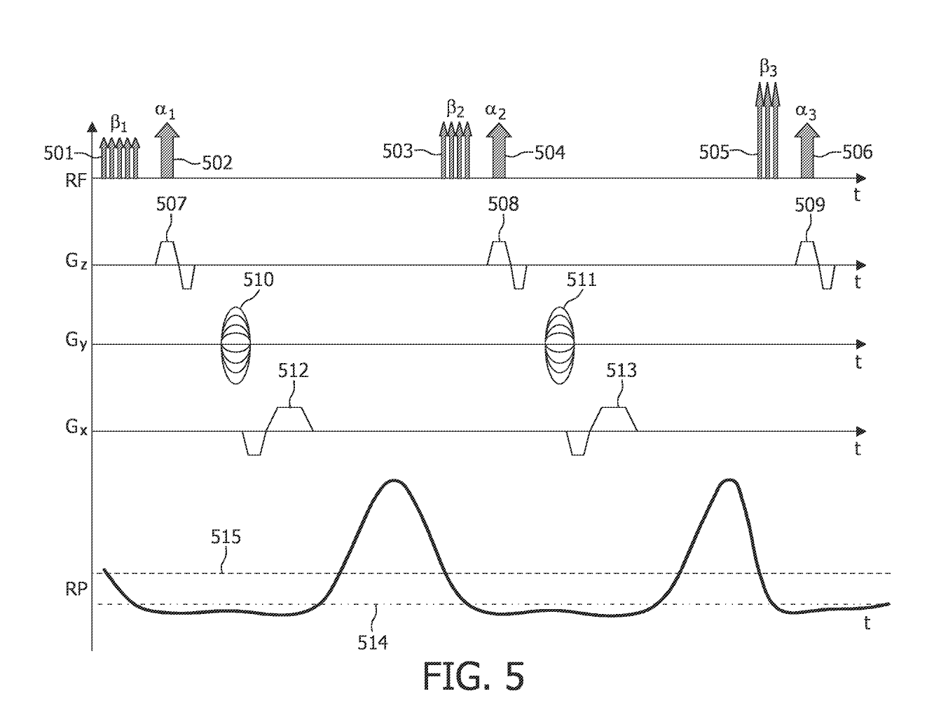

FIG. 5 diagrammatically shows a gradient echo pulse waveform, wherein an RF pulse has been regulated by adjusting its pulse amplitude as well as number of pulses, depending on the rate of change of a motion of a subject, and

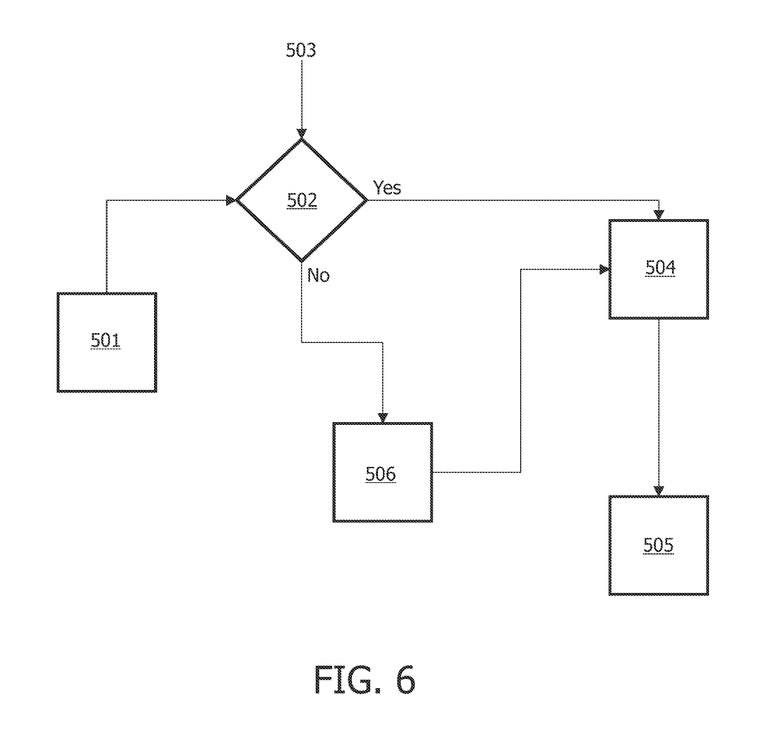

FIG. 6 shows a method according to the invention, wherein the method provides increased comfort and safety of a subject being examined.

It may be noted that corresponding reference numerals used in the various figures represent corresponding structures in the figures.

FIG. 1 is a block diagram of an MR imaging system according to the invention. The MR imaging system comprises a set of main coils 101, multiple gradient coils 102 connected to a gradient driver unit 106, and RF coils 103 connected to an RF coil driver unit 107. The function of the RF coils 103, which may be integrated into the magnet in the form of a body coil, or may be separate surface coils, is further controlled by a transmit/receive (T/R) switch 113. The multiple gradient coils 102 and the RF coils are powered by a power supply unit 112. A transport system 104, for example a patient table, is used to position a subject 105, for example a patient, within the MR imaging system. A monitoring device 117 to monitor a characteristic of a motion, for example a mercury strain gauge to monitor chest wall displacement, is removably attached to the chest of the patient. Alternatively, the MR apparatus itself can be employed to monitor patient motion, e.g. by means of navigator signals. The monitored characteristic is compared to a limit 119 by a comparator device 118, and the output signal of the comparator device is fed to a control unit 108. The control unit 108 also acts as a pulse sequencer unit, by controlling the application of RF and gradient pulses. Alternatively, the control unit 108 may control an external pulse sequencer circuit (not shown). The control unit 108 further controls the operation of a reconstruction unit 109, a display unit 110, for example a monitor screen or a projector, a data storage unit 115, and a user input interface unit 111, for example, a keyboard, a mouse, a trackball, etc. A real-time SAR monitor 116 keeps track of the SAR of the subject, based on the RF pulses applied.

The main coils 101 generate a steady and uniform static magnetic field, for example, of field strength 1.5 T or 3 T. The invention is applicable to any other field strength as well. The main coils 101 are arranged in such a way that they typically enclose a tunnel-shaped examination space, into which the subject 105 may be introduced. Another common configuration comprises opposing pole faces with an air gap in between them into which the subject 105 may be introduced by using the transport system 104. To enable MR imaging, temporally variable magnetic field gradients superimposed on the static magnetic field are generated by the multiple gradient coils 102 in response to currents supplied by the gradient driver unit 106. The power supply unit 112, fitted with electronic gradient amplification circuits, supplies currents to the multiple gradient coils 102, as a result of which gradient pulses (also called gradient pulse waveforms) are generated. The control unit 108 controls the characteristics of the currents, notably their strengths, durations and directions, flowing through the gradient coils to create the appropriate gradient waveforms. The RF coils 103 generate RF excitation pulses in the subject 105 and receive MR signals generated by the subject 105 in response to the RF excitation pulses. The RF coil driver unit 107 supplies current to the RF coil 103 to transmit the RF excitation pulse, and amplifies the MR signals received by the RF coil 103. The transmitting and receiving functions of the RF coil 103 or set of RF coils are controlled by the control unit 108 via the T/R switch 113. The T/R switch 113 is provided with electronic circuitry that switches the RF coil 103 between transmit and receive modes, and protects the RF coil 103 and other associated electronic circuitry against breakthrough or other overloads, etc. The characteristics of the transmitted RF excitation pulses, notably their strength and duration, are controlled by the control unit 108.

A characteristic of a motion of the subject 105 is monitored using a monitoring device 117, for example a wrap-around strain gauge. Further examples of monitoring systems for motion comprise high-resolution cameras or video cameras to capture a time series of images, or using an ultrasound scanner, etc. Also, the MR apparatus itself can be employed to monitor motion by means of navigator signals. The signal from the monitoring device 117 is fed to a comparator device 118, which compares the signal to a limit value 119. The limit 119 may be pre-determined and fixed, or alternatively, could be dynamically determined and even adjusted during the scan. If the characteristic of the motion exceeds the limit value, the comparator device 118 signals the control unit 108 to regulate a characteristic of the pulse waveform. For example, when the displacement of the chest wall, being monitored by the strain gauge, crosses the limit 119, the comparator 118 signals the control unit 108 to stop the application of the next RF pulse. In addition, based on the situation, the control unit 108 may additionally stop the application of further gradient pulses, like a readout gradient. When the displacement of the chest wall is within the limit, the comparator device 118 instructs the control unit 108 to resume pulsing.

The real-time SAR monitor 116 monitors the amount of RF energy deposited in the subject 105, by monitoring the power, duration and number of pulses applied in a particular period of time. If the RF energy being deposited by a pulse sequence exceeds regulatory or legal limits of SAR, the real-time SAR monitor 116 signals the control unit 108 to control the application of RF pulses. The control unit 108, in turn, signals the T/R switch 113 to pause the application of RF pulses, or to adapt the RF power, until the SAR levels in the subject return to within regulatory or legal limits.

It is to be noted that though the transmitting and receiving coil are shown as one unit in this embodiment, it is also possible to have separate coils for transmission and reception, respectively. It is further possible to have multiple RF coils 103 for transmitting or receiving or both. The RF coils 103 may be integrated into the magnet in the form of a body coil, or may be separate surface coils. They may have different geometries, for example, a birdcage configuration or a simple loop configuration, etc. The control unit 108 is preferably in the form of a computer that includes a processor, for example a microprocessor. The control unit 108 controls, via the T/R switch 113, the application of RF pulse excitations and the reception of MR signals comprising echoes, free induction decays, etc. User input interface devices 111 like a keyboard, mouse, touch-sensitive screen, trackball, etc., enable an operator to interact with the MR system.

The MR signal received with the MR antennae 103 contains the actual information concerning the local spin densities in a region of interest of the subject 105 being imaged. The received signals are reconstructed by the reconstruction unit 109, and displayed on the display unit 110 as an MR image or an MR spectrum. It is alternatively possible to store the signal from the reconstruction unit 109 in a storage unit 115, while awaiting further processing. The reconstruction unit 109 is constructed advantageously as a digital image-processing unit that is programmed to derive the MR signals received from the RF coils 103.

FIG. 2 diagrammatically shows a pulse sequence useful for MR spectroscopy. The axis marked RF shows the sequence of RF pulses 201 to 204, the axis marked RO shows the readout of the free induction decay (FID) signals 205 to 208, and the axis marked RP shows the variation of the monitored motion of the subject. The left-to-right direction is the time axis, marked by the letter ‘t’. The line 209 shows the limit for the monitored motion.

An α pulse, typically a 90° pulse is applied to a subject, for example a region of the brain or the heart of a patient. The RF pulse excites a certain species of nuclei, for example, proton (¹H), phosphorus (³¹P), sodium (²³Na), etc. Immediately after the RF pulse is applied, an MR signal in the form of a free induction decay (FID) is acquired from the sample. The FID is then Fourier transformed in one dimension to get a spectrum comprising peaks that indicate the concentration of various compounds in the sample. If the FID signals are being acquired from a part of the brain, for example, then the position of the head is monitored. If the head moves beyond a certain threshold value, denoted in the figure by line 209, the application of the RF pulse is stopped, as indicated by the “dotted” RF pulses 202 and 204. When the head moves back to within the threshold, the RF pulses are restarted. This ensures that the RF pulses are applied only when useful data can be acquired from the subject. This reduces the SAR exposure of the subject, as well as reduces heating effects, leading to increased safety and comfort of the patient.

FIG. 3 diagrammatically shows an echo planar imaging (EPI) sequence, wherein the axis labelled RF shows the application of RF pulses 301, 302 of flip angles α₁, α₂, respectively, separated by a repetition time interval TR. A slice select gradient 303, 304 is applied together with the RF pulse 301, 302, respectively, as depicted along the axis labelled G_{z}. Phase encoding gradients in the form of a prewinder gradient 305, 308, as well as a series of blip gradients 306, 307, 309, 310, 330, 331, are applied as shown by the axis labelled G_{y}. Readout or frequency encoding gradients 311, 312, . . . 328 are applied along the Gₓ axis to acquire MR data. The motion of the subject is monitored as shown by the axis labelled RP, and a pre-determined limit value is set as shown by the line 329.

In the current embodiment, for example, the motion of the heart is monitored by monitoring the subject's heartbeat using an ultrasound scanning system. Alternatively, the heartbeat may be monitored using an MR navigator pulse sequence. The trace RP is shown as an illustrative trace only. The heart moves the most during the ventricular systole phase, denoted by the peaks A and C on the trace RP. When the motion is below the cut-off value 329, MR data are acquired, as shown by the readout gradients 311, 314 to 318, 323 to 328. Phase encoding gradients 306, 330, 331 are also applied. When the characteristic of the motion rises above or otherwise exceeds the cut-off value 329, the readout gradients are minimized, as shown by the “dotted-line” gradients 312, 313, 319, and 320 to 322. The corresponding phase encoding gradients 307, 331, and 309 are stopped or minimized. When the characteristic of the motion returns to within the pre-determined cut-off value, MR data are again acquired, as shown by the gradient pulses 314 to 318, and 323 to 328. Minimizing the gradients without turning them off completely reduces the ramp-up time for subsequent gradients, and thus reduces the load on the gradient driver circuits. The smaller gradients further lead to reduced noise levels in the bore of a MR imaging system, leading to improved patient comfort.

FIG. 4 diagrammatically shows an illustrative implementation of the method of the invention. Various RF pulses 401 and gradient pulses 402 are prepared for application as part of a pulse sequence. The trace RP shows the change in a characteristic of a motion being monitored, with the line 403 showing the acceptable limit of the characteristic of the motion. The amount of RF energy deposited in a subject is monitored by a SAR monitor 404, by taking into account all the RF pulses that are applied during a specified duration of time.

If the motion characteristic, e.g. the diaphragmatic position of the patient, is not within predefined limits 403, the RF pulse and can be reduced to a minimum, or switched off completely. Also, gradient amplitudes can be reduced or eliminated, respectively. If a “good” respiratory position is detected, and the successively measured data contribute to the reconstructed image, optimal RF power is resumed.

Given a typical breathing pattern, approximately 50% of the data are acquired in a “good” respiratory position, and 50% have to be rejected due to motion, and need to be re-measured at a later point in time. Hence, switching off RF power during the acquisition of these data yields a reduction of the SAR deposition of 50% averaged over time. This improves patient comfort and safety. Alternatively, this may allow applying higher flip angles or shorter repetition times between RF pulses to optimize image quality without exceeding SAR limits. Some of the many possible areas of application of the invention are MR sequences which require high RF power, such as spin echo sequences, or steady-state free precession (SSFP) sequences.

In theory, SSFP can be attained by applying a spin echo or a gradient echo sequence where the TR is shorter than the T₁ and the T₂ relaxation times of the tissue being examined. By proper selection of the flip angle and the TR, a non-zero steady state is maintained for both the transverse as well as the longitudinal magnetization. For example, for typical proton imaging, for a TR of 100 ms, the flip angle should be around 60° to 90°. For shorter TRs, smaller flip angles of typically 45° to 60° may be used. Further information on SSFP may be found in Oppelt A, Graumann R, Barfuss H. “FISP: A New Fast MRI Sequence”, Electromedica, volume 54, pages 15-18 (1986).

As shown in the illustrative figure, it is possible to block only those pulses that fall during the time when the monitored motion exceeds the threshold. For example, even though the magnetization has been prepared by the application of a slice select pulse and a phase encode pulse, the corresponding readout gradient may be blocked if it coincides with the time when the monitored motion exceeds the threshold. Though this technique in itself yields an improvement in patient comfort and safety by eliminating unproductive pulses, regulating individual pulse waveforms within a particular pulse sequence may not yield optimal image quality. Hence it may be desirable to block an entire pulse sequence so that only the data relatively unaffected by motion is acquired.

Further improvement in patient comfort and safety may be achieved by incorporating a predictive model for the motion being monitored. By considering the history of previous periodic motion, it is statistically possible to predict the next cycle of the motion. If the statistical model predicts that a particular acquisition or readout gradient would be most likely turned off due to excessive motion, the application of the preparatory pulses can also be stopped, and later restarted when the characteristic of the motion is within limits. In other words, the application of the entire pulse train is started only if the predictive model determines that all pulses from excitation or refocusing to acquisition can be applied. The predictive model may be implemented by the control unit 108 of FIG. 1, either as a software program, or in hardware.

FIG. 5 shows a pulse sequence timing diagram for a gradient echo sequence. The RF axis shows a series of RF pulses, comprising preparatory pulses 501, 503, 505 of flip angles β₁, β₂, and β₃, respectively, and excitation pulses 502, 504, 506 of flip angles α₁, α₂, and α₃, respectively. The G_{z} axis denotes the slice select gradients 507, 508, 509 associated with the excitation pulses 502, 504, 506, respectively. The G_{y} axis shows the phase encoding gradients 510, 511, while the Gₓ axis denotes the readout gradients 512, 513. The RP trace shows the change in a motion being monitored, with the lines 514 and 515 depicting a first and a second limit, respectively.

As seen in the figure, the optimal time to image is when the motion is below the threshold 514, as this corresponds to the time period of least motion. In order to make optimal use of this “quiet” time period, it is advantageous to attain the required steady state just before the start of the imaging sequence during the quiet phase. The preparatory pulses 501, 503, 505 are therefore applied during a time when the monitored motion is still above the threshold 514, but below the threshold 515. The rate of change of motion is monitored between the threshold lines 514 and 515, and the number or the amplitude of the RF pulses 501, 503, 505 is regulated accordingly. Such a step might be useful, for example, in quickly establishing a steady state condition by applying a large flip angle RF pulse just prior to start of imaging, especially when using SSFP sequences.

FIG. 6 schematically represents an implementation of the method according to the invention. A characteristic of a motion is monitored in a step 501 and compared in a step 502 to a limit applied by a step 503. If a condition for the characteristic of the motion is satisfied, for example, the monitored characteristic of the motion is within the limit, then the pulse sequence is applied with no regulation of RF or gradient pulses, as shown in step 504, and MR data are acquired in step 505. If the condition for the characteristic is not satisfied in step 502, the pulse sequence parameters are adjusted in step 506. The regulated pulse waveform is applied to the subject in step 504, and MR data are acquired in step 505.

In general, RF pulses may comprise one or more excitation pulses of various flip angles, for example excitation pulses, 180° inversion pulses, 180° refocusing pulses, etc. Gradient pulses may comprise gradient waveforms that are applied in conjunction with RF pulses, for example slice-selective excitation or refocusing pulses, spectral-spatial pulses, etc. Gradient pulses may further comprise gradient waveforms applied independent of RF pulses, for example as phase encoding pulses, readout or frequency encoding gradient pulses, phase rewinder pulses, crusher gradient pulses, etc.

Multiple limits could be prescribed for each of the characteristics of the motion being monitored. The limits could be prescribed concurrently or otherwise. For example, both the speed of motion as well as the displacement could be simultaneously monitored, and the pulse waveform regulated accordingly. It is also possible to monitor characteristics of different motions, for example respiratory motion and heart motion of the same patient, and regulate the pulse waveforms based on both motion measurements simultaneously. It is also further possible to monitor the motion of two different subjects, for example, while imaging a foetus in its mother's womb. The motion caused by the mother's respiration may be monitored using a strain gauge, and used together with the foetus' heart rate measured using an ultrasound technique, to calculate optimal imaging periods.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements, and by means of a suitably programmed computer. In the system claims enumerating several means, several of these means can be embodied by one and the same item of computer readable software or hardware. The mere fact that certain measures are recited in mutually different dependent claims does not indicate that a combination of these measures cannot be used to advantage.

It should further be noted that the figures are not drawn to scale. Time scales as shown in the various figures are only illustrative, and do not represent actual pulse sequence timings or time for motion to occur.

1. A magnetic resonance system for acquiring magnetic resonance data from a subject, the magnetic resonance system comprising
a monitoring module for monitoring a characteristic of a motion of the subject, the characteristic of the motion having a limit, and
a pulse sequencer for applying a pulse sequence to acquire data from the subject, the pulse sequence comprising at least one pulse waveform,
wherein the pulse sequencer is further arranged to regulate a characteristic of the at least one pulse waveform when the characteristic of the motion surpasses the limit.

2. A system as claimed in claim 1, wherein
the at least one pulse waveform comprises a radio frequency pulse.

3. A system as claimed in claim 1, wherein
the at least one pulse waveform further comprises a gradient pulse.

4. A system as claimed in claim 2, wherein
the characteristic of the at least one pulse waveform, for example the pulse amplitude or the pulse width, is adjusted to a minimum value, preferably zero.

5. A method of acquiring magnetic resonance data from a subject, the method comprising the steps of
monitoring a characteristic of a motion of the subject, the characteristic of the motion having a limit,
applying a pulse sequence to acquire data from the subject, the pulse sequence comprising at least one pulse waveform, and
regulating a characteristic of the at least one pulse waveform when the characteristic of the motion surpasses the limit.

6. A computer program for a magnetic resonance system as claimed in claim 1, the computer program further comprising instructions for
monitoring a characteristic of a motion of a subject, the characteristic of the motion having a limit,
applying a pulse sequence to acquire data from the subject the pulse sequence comprising at least one pulse waveform, and
regulating a characteristic of the at least one pulse waveform when the characteristic of the motion surpasses the limit,
when the computer program is run on a computer.
